(19) United States
(12) Patent Application Publication
(10) Pub. No.: US 2024/0349480 A1
(43) Pub. Date: Oct. 17, 2024

(54) SEMICONDUCTOR DEVICE AND METHOD OF FORMING THE SAME

(71) Applicant: MICRON TECHNOLOGY, INC., BOISE, ID (US)

(72) Inventor: Naokazu Murata, Higashihiroshima (JP)

(73) Assignee: MICRON TECHNOLOGY, INC., Boise, ID (US)

(21) Appl. No.: 18/623,552

(22) Filed: Apr. 1, 2024

Related U.S. Application Data
(60) Provisional application No. 63/496,493, filed on Apr. 17, 2023.

(51) Int. Cl. H10B 12/00

(52) U.S. Cl. CPC H10B 12/09; H10B 12/315; H10B 12/50

(57) ABSTRACT

An apparatus includes: a semiconductor substrate having a first region, a second region and a third region; a first wiring above the first region of the semiconductor substrate; a second wiring above the second region of the semiconductor substrate; a third wiring above the third region of the semiconductor substrate; and a first insulating film on each of the first, second and third wirings. A height of an upper surface of the first wiring is lower than a height of an upper surface of the second wiring; wherein the height of an upper surface of the second wiring is lower than a height of an upper surface of the third wiring Each of portions of the first insulating film disposed above the first, second and third wirings has an equal film thickness.

### CROSS-REFERENCE TO RELATED APPLICATIONS

This application claims the filing benefit of U.S. Provisional Application No. 63/496,493, filed Apr. 17, 2023. This application is incorporated by reference herein in its entirety and for all purposes.

### BACKGROUND

Recently, in semiconductor devices such as dynamic random access memory (DRAM), increased memory capacity is desired, and increases in memory capacity are being achieved with finer processing dimensions. However, this results in a thinner insulating film over the wirings, and shorts between wirings may occur in some cases.

### BRIEF DESCRIPTION OF THE DRAWINGS

FIG. 1 is a longitudinal section illustrating a schematic configuration of a memory cell region of a semiconductor device according to an embodiment;

FIG. 2 is a longitudinal section illustrating a schematic configuration of a sense amplifier/sub-word driver region of a semiconductor device according to an embodiment;

FIG. 3 is a longitudinal section illustrating a schematic configuration of a peripheral circuit region of a semiconductor device according to an embodiment;

FIGS. 4, 5, 6 are diagrams illustrating a method of forming a semiconductor device according to an embodiment, and each is a longitudinal section illustrating the schematic configuration of the semiconductor device in an exemplary process stage. FIG. 4 is a longitudinal section illustrating a schematic configuration of a memory cell region of a semiconductor device according to an embodiment. FIG. 5 is a longitudinal section illustrating a schematic configuration of a sense amplifier or sub-word driver region of a semiconductor device according to an embodiment. FIG. 6 is a longitudinal section illustrating a schematic configuration of a peripheral circuit region of a semiconductor device according to an embodiment;

FIGS. 7, 8, and 9 are diagrams illustrating a method of forming a semiconductor device according to an embodiment, and each is a longitudinal section illustrating the schematic configuration of the semiconductor device in an exemplary process stage subsequent to FIGS. 4, 5, and 6. FIG. 7 is a longitudinal section illustrating a schematic configuration of a memory cell region of a semiconductor device according to an embodiment. FIG. 8 is a longitudinal section illustrating a schematic configuration of a sense amplifier or sub-word driver region of a semiconductor device according to an embodiment. FIG. 9 is a longitudinal section illustrating a schematic configuration of a peripheral circuit region of a semiconductor device according to an embodiment;

FIGS. 10, 11, and 12 are diagrams illustrating a method of forming a semiconductor device according to an embodiment, and each is a longitudinal section illustrating the schematic configuration of the semiconductor device in an exemplary process stage subsequent to FIGS. 7, 8, and 9. FIG. 10 is a longitudinal section illustrating a schematic configuration of a memory cell region of a semiconductor device according to an embodiment. FIG. 11 is a longitudinal section illustrating a schematic configuration of a sense amplifier or sub-word driver region of a semiconductor device according to an embodiment. FIG. 12 is a longitudinal section illustrating a schematic configuration of a peripheral circuit region of a semiconductor device according to an embodiment;

FIGS. 13, 14, and 15 are diagrams illustrating a method of forming a semiconductor device according to an embodiment, and each is a longitudinal section illustrating the schematic configuration of the semiconductor device in an exemplary process stage subsequent to FIGS. 10, 11, and 12. FIG. 13 is a longitudinal section illustrating a schematic configuration of a memory cell region of a semiconductor device according to an embodiment. FIG. 14 is a longitudinal section illustrating a schematic configuration of a sense amplifier or sub-word driver region of a semiconductor device according to an embodiment. FIG. 15 is a longitudinal section illustrating a schematic configuration of a peripheral circuit region of a semiconductor device according to an embodiment;

FIGS. 16, 17, and 18 are diagrams illustrating a method of forming a semiconductor device according to an embodiment, and each is a longitudinal section illustrating the schematic configuration of the semiconductor device in an exemplary process stage subsequent to FIGS. 13, 14, and 15. FIG. 16 is a longitudinal section illustrating a schematic configuration of a memory cell region of a semiconductor device according to an embodiment. FIG. 17 is a longitudinal section illustrating a schematic configuration of a sense amplifier or sub-word driver region of a semiconductor device according to an embodiment. FIG. 18 is a longitudinal section illustrating a schematic configuration of a peripheral circuit region of a semiconductor device according to an embodiment;

FIGS. 19, 20, and 21 are diagrams illustrating a method of forming a semiconductor device according to an embodiment, and each is a longitudinal section illustrating the schematic configuration of the semiconductor device in an exemplary process stage subsequent to FIGS. 16, 17, and 18. FIG. 19 is a longitudinal section illustrating a schematic configuration of a memory cell region of a semiconductor device according to an embodiment. FIG. 20 is a longitudinal section illustrating a schematic configuration of a sense amplifier or sub-word driver region of a semiconductor device according to an embodiment. FIG. 21 is a longitudinal section illustrating a schematic configuration of a peripheral circuit region of a semiconductor device according to an embodiment; and

FIGS. 22, 23, and 24 are diagrams illustrating a method of forming a semiconductor device according to an embodiment, and each is a longitudinal section illustrating the schematic configuration of the semiconductor device in an exemplary process stage subsequent to FIGS. 19, 20, and 21. FIG. 22 is a longitudinal section illustrating a schematic configuration of a memory cell region of a semiconductor device according to an embodiment. FIG. 23 is a longitudinal section illustrating a schematic configuration of a sense amplifier or sub-word driver region of a semiconductor device according to an embodiment. FIG. 24 is a longitudinal section illustrating a schematic configuration of a peripheral circuit region of a semiconductor device according to an embodiment.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

Hereinafter, a semiconductor device and a method of forming the same according to an embodiment will be described with reference to the drawings. In the following description, dynamic random access memory (hereinafter referred to as DRAM) is given as an example of the semiconductor device. In the description of the embodiment, common or related elements and elements that are substantially the same are denoted with the same signs, and the description thereof will be reduced or omitted. In the drawings referenced hereinafter, the dimensions and dimensional ratios of each unit in each of the drawings do not necessarily match the dimensions and dimensional ratios in the embodiment. Furthermore, in the following description, the Y direction is the direction at a right angle to the X direction. Also, the Z direction is the direction at a right angle to the X-Y plane defined as the plane of a semiconductor substrate, and is also referred to as the vertical direction.

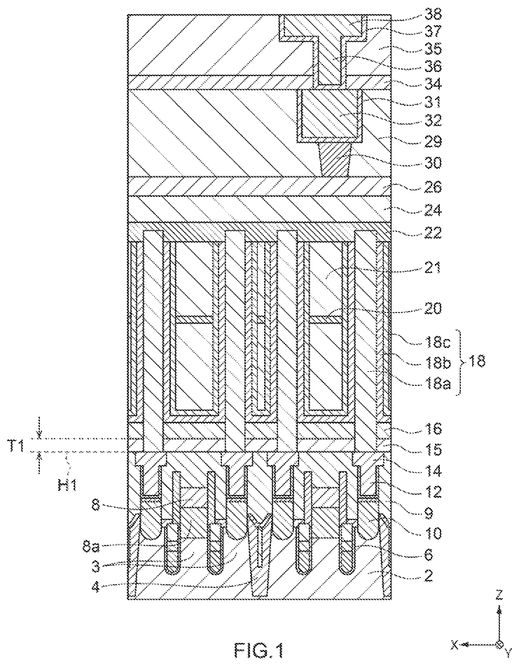

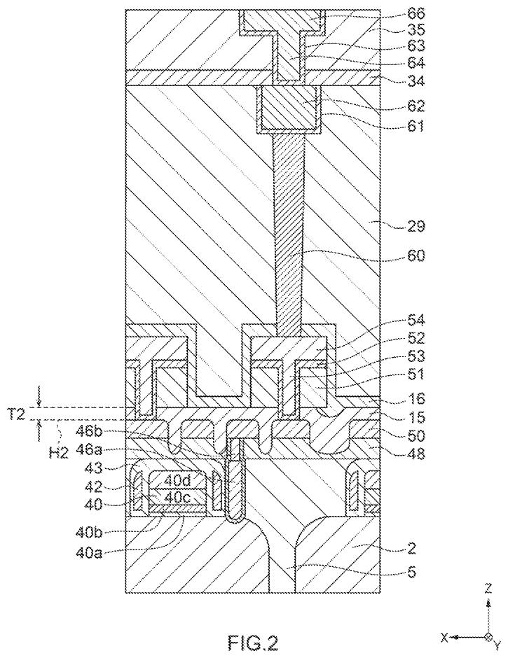

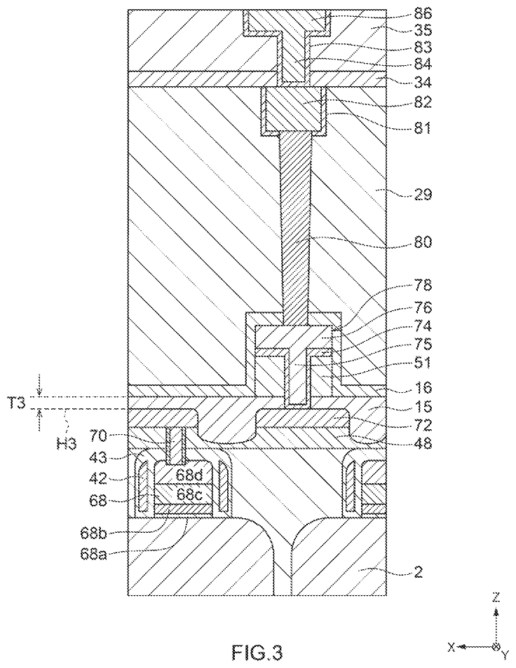

Hereinafter, the semiconductor device according to the embodiment will be described. FIGS. 1, 2, and 3 illustrate a schematic configuration of a semiconductor device formed on a semiconductor substrate 2. FIG. 1 illustrates a schematic configuration of a memory cell region. FIG. 2 illustrates a schematic configuration of a sense amplifier or sub-word driver region (SA/SWD region). The sense amplifier or sub-word driver is connected to the memory cell region. FIG. 3 illustrates a schematic configuration of a peripheral circuit region.

As illustrated in FIG. 1, an isolation 4, word lines 6, bit lines 8, and capacitors 18 are provided on the semiconductor substrate 2. The region other than the isolation 4 is an active region 3. The semiconductor substrate 2 includes a disc-shaped single-crystal silicon wafer provided with a main surface that has been given a mirror finish, for example. The isolation 4 includes a plurality of insulating films embedded in trenches formed in the semiconductor substrate 2, for example.

As illustrated in FIG. 1, the plurality of word lines 6 each extend in the X direction. The word lines 6 include a layered film of a plurality of conducting films. The plurality of bit lines 8 each extend in the Y direction. The bit lines 8 include a layered film of a plurality of conducting films. The word lines 6 and bit lines 8 contain conducting materials such as polysilicon, titanium nitride (TiN), and tungsten (W) doped with an impurity such as phosphorus, arsenic, or boron, for example.

The bit lines 8 are connected to the active region 3 through a bit line contact 8a in the region adjacent to one of the word lines 6 in the X direction. The capacitors 18 are connected to the active region 3 through a first capacitor contact plug 10, a second capacitor contact plug 12, and a pad 14 in the region adjacent to another of the word lines 6 in the X direction. The first capacitor contact plug 10 and the second capacitor contact plug 12 contain conducting materials such as titanium nitride (TiN) and tungsten (W), for example. The first capacitor contact plug 10, the second capacitor contact plug 12, and the pad 14 penetrate through a first interlayer insulating film 9 provided on the isolation 4 and the bit lines 8. The pad 14 contains a conducting material such as tungsten, for example.

The capacitors 18 are provided with a multilayer film of a first capacitor electrode 18a, a capacitance insulating film 18b, and a second capacitor electrode 18c. The first capacitor electrode 18a contains a conducting material such as titanium nitride (TiN), for example. The capacitance insulating film 18b contains an insulating material such as zirconium oxide (ZrOx), for example. The second capacitor electrode 18c contains a conducting material such as titanium nitride, for example.

The first capacitor electrode 18a penetrates through a second interlayer insulating film 15 and a third interlayer insulating film 16 provided on the first interlayer insulating film 9 and the pad 14. The second capacitor electrode 18c has a pillar shape and extends in the Z direction.

The capacitance insulating film 18b and the second capacitor electrode 18c are provided on the sides of the first capacitor electrode 18a. The capacitors 18 are interconnected by beams 20 and upper capacitor insulation 22. An inter-capacitor insulating film 21 is embedded between the capacitors 18. The beams 20 contain an insulating material such as silicon nitride (SiN), for example. The inter-capacitor insulating film 21 contains an insulating material such as silicon dioxide (SiO₂), for example. The upper capacitor insulation 22 is provided on top of the capacitors 18 and the inter-capacitor insulating film 21. The upper capacitor insulation 22 contains an insulating material such as silicon nitride, for example.

On top of the upper capacitor insulation 22, a first plate electrode 24 and a second plate electrode 26 are provided. The first plate electrode 24 contains a conducting material such as polysilicon doped with phosphorus or arsenic, for example. The second plate electrode 26 contains a conducting material such as tungsten, for example. The first plate electrode 24 and the second plate electrode 26 are connected to the second capacitor electrode 18c in a different location not illustrated in the drawings.

A fourth interlayer insulating film 29 is provided on top of the second plate electrode 26. The fourth interlayer insulating film 29 contains an insulating material such as silicon dioxide, for example. On the upper surface of the second plate electrode 26, a first upper wiring contact plug 30 is connected to the second plate electrode 26. The first upper wiring contact plug 30 contains a conducting material such as tungsten, for example. A seed layer 31 and a first upper wiring 32 are connected to the first upper wiring contact plug 30. The seed layer 31 covers the lower and side surfaces of the first upper wiring 32. The seed layer 31 contains a conducting material such as titanium or a copper (Cu) alloy, for example. The first upper wiring 32 contains a conducting material such as copper, for example. The first upper wiring contact plug 30 and the first upper wiring 32 penetrate through the fourth interlayer insulating film 29.

A fifth interlayer insulating film 34 and a sixth interlayer insulating film 35 are disposed on the fourth interlayer insulating film 29, the seed layer 31, and the first upper wiring 32. The fifth interlayer insulating film 34 contains an insulating material such as silicon nitride, for example. The sixth interlayer insulating film 35 contains an insulating material such as silicon dioxide, for example. A seed layer 37, a second wiring contact plug 36, and a second upper wiring 38 are connected to the first upper wiring 32. The second wiring contact plug 36 and the second upper wiring 38 are configured as one, without a boundary. The seed layer 37 covers the lower and side surfaces of the second wiring contact plug 36 and the second upper wiring 38. The seed layer 37 contains a conducting material such as titanium or a copper alloy, for example. The second wiring contact plug 36 and the second upper wiring 38 contain a conducting material such as copper, for example.

As illustrated in FIG. 2, in the sense amplifier or sub-word driver region, a first peripheral transistor gate 40 of a transistor forming the circuit of a sense amplifier or a sub-word driver is provided on the semiconductor substrate 2 where an isolation 5 is provided. The first peripheral transistor gate 40 is provided with a first conducting section 40b, a second conducting section 40c, and a third conducting section 40d on a gate insulating film 40a provided on the semiconductor substrate 2. The gate insulating film 40a contains an insulating material such as silicon dioxide, for example. The first conducting section 40b, the second conducting section 40c, and the third conducting section 40d contain conducting materials. The first conducting section 40b contains titanium nitride, for example. The second conducting section 40c contains polysilicon doped with an impurity such as phosphorus, arsenic, or boron, for example. The third conducting section 40d contains tungsten, for example.

A sidewall insulating film 42 is provided on the side surfaces of the first peripheral transistor gate 40. The first peripheral transistor gate 40 and the sidewall insulating film 42 are covered by an insulating film 43. The sidewall insulating film 42 contains silicon dioxide, for example. The insulating film 43 contains silicon nitride, for example. A first wiring lower contact plug 46a is provided beside the first peripheral transistor gate 40. The first wiring lower contact plug 46a contains tungsten surrounded and covered by a barrier metal including titanium and titanium nitride.

A peripheral interlayer insulating film 48 is provided on the first peripheral transistor gate 40. The peripheral interlayer insulating film 48 contains silicon nitride, for example. A plurality of first wirings 50 are provided on the peripheral interlayer insulating film 48. The first wiring 50 contains a conducting material such as tungsten, for example. The second interlayer insulating film 15 is provided on top of the first wiring 50. The second interlayer insulating film 15 contains silicon dioxide, for example. The first wiring 50 and the first wiring lower contact plug 46a are connected by a first wiring upper contact plug 46b. The first wiring upper contact plug 46b penetrates through the peripheral interlayer insulating film 48. The first wiring upper contact plug 46b contains tungsten surrounded and covered by a barrier metal including titanium and titanium nitride.

A second wiring contact plug 53 and a second wiring 54 are provided on the second interlayer insulating film 15. The lower and side surfaces of the second wiring contact plug 53 and the second wiring 54 are covered by a barrier metal 52. The second wiring contact plug 53 penetrates through the second interlayer insulating film 15, and the first wiring 50 and the second wiring contact plug 53 are connected through the barrier metal 52. The second wiring contact plug 53 and the second wiring 54 are configured as one, without a boundary in between. The second wiring contact plug 53 and the second wiring 54 contain a conducting material such as tungsten, for example. The barrier metal 52 contains titanium and titanium nitride. An under-wiring insulating film 51 is provided between the second wiring 54 and the second interlayer insulating film 15. The under-wiring insulating film 51 contains silicon dioxide, for example. The upper and side surfaces of the second interlayer insulating film 15, the second wiring 54, and the under-wiring insulating film 51 are covered by the third interlayer insulating film 16. The third interlayer insulating film 16 contains silicon nitride, for example.

The fourth interlayer insulating film 29 is provided on top of the third interlayer insulating film 16. A first upper wiring contact plug 60 is connected to the second wiring 54. A seed layer 61 and a first upper wiring 62 are connected to the first upper wiring contact plug 60. The first upper wiring contact plug 60 and the first upper wiring 62 penetrate through the fourth interlayer insulating film 29. The first upper wiring contact plug 60, the seed layer 61, and the first upper wiring 62 are each included in the same layer as the first upper wiring contact plug 30, the seed layer 61, and the first upper wiring 32 described above, and contain the same materials.

The fifth interlayer insulating film 34 and the sixth interlayer insulating film 35 are disposed on the fourth interlayer insulating film 29, the seed layer 61, and the first upper wiring 62. A seed layer 63, a second upper wiring contact plug 64, and a second upper wiring 66 are connected to the first upper wiring 62. The second upper wiring contact plug 64 and the second upper wiring 66 are configured as one, without a boundary. The seed layer 63 covers the lower and side surfaces of the second upper wiring contact plug 64 and the second upper wiring 66. The seed layer 63, the second upper wiring contact plug 64, and the second upper wiring 66 are included in the same layer as the seed layer 37, the second wiring contact plug 36, and the second upper wiring 38 described above, and contain the same materials.

As illustrated in FIG. 3, in the peripheral circuit region, a second peripheral transistor gate 68 of a transistor forming a peripheral circuit is provided on the semiconductor substrate 2 where the isolation 5 is provided. The second peripheral transistor gate 68 is provided with a first conducting section 68b, a second conducting section 68c, and a third conducting section 68d on a gate insulating film 68a provided on the semiconductor substrate 2. The gate insulating film 68a, the first conducting section 68b, the second conducting section 68c, and the third conducting section 68d are each included in the same layer as the gate insulating film 40a, the first conducting section 40b, the second conducting section 40c, and the third conducting section 40d described above, and contain the same materials.

The sidewall insulating film 42 is provided on the side surfaces of the second peripheral transistor gate 68. A third wiring contact plug 70 is connected to an upper portion of the second peripheral transistor gate 68. The third wiring contact plug 70 contains tungsten surrounded and covered by a barrier metal including titanium and titanium nitride.

The peripheral interlayer insulating film 48 is provided on the second peripheral transistor gate 68. A third wiring 72 is provided on the peripheral interlayer insulating film 48. The third wiring contact plug 70 is included in the same layer as the first wiring 50, and contains the same material. The second interlayer insulating film 15 is provided on top of the third wiring 72. A fourth wiring contact plug 75 and a fourth wiring 76 are provided on the upper surface of the third wiring 72. The lower and side surfaces of the fourth wiring contact plug 75 and the fourth wiring 76 are covered by a barrier metal 74. The fourth wiring contact plug 75 penetrates through the second interlayer insulating film 15, and the first wiring 50 and the fourth wiring contact plug 75 are connected through the barrier metal 74. The fourth wiring contact plug 75 and the fourth wiring 76 are configured as one, without a boundary in between. The barrier metal 74, the fourth wiring contact plug 75, and the fourth wiring 76 are included in the same layer as the barrier metal 52, the second wiring contact plug 53, and the second wiring 54, and contain the same materials. The under-wiring insulating film 51 is provided between the fourth wiring 76 and the second interlayer insulating film 15. The upper and side surfaces of the second interlayer insulating film 15, the fourth wiring 76, and the under-wiring insulating film 51 are covered by the third interlayer insulating film 16.

The fourth interlayer insulating film 29 is provided on top of the third interlayer insulating film 16. A third upper wiring contact plug 80 is connected to the fourth wiring 76 on the upper surface of the fourth wiring 76. A seed layer 81 and a third upper wiring 82 are connected to the third upper wiring contact plug 80. The seed layer 81 covers the lower and side surfaces of the third upper wiring 82. The third upper wiring contact plug 80 and the third upper wiring 82 penetrate through the fourth interlayer insulating film 29. The third upper wiring contact plug 80, the seed layer 81, and the third upper wiring 82 are each included in the same layer as the first upper wiring contact plug 30, the seed layer 31, and the first upper wiring 32 described above, and contain the same materials.

The fifth interlayer insulating film 34 and the sixth interlayer insulating film 35 are disposed on the fourth interlayer insulating film 29, the seed layer 81, and the third upper wiring 82. A seed layer 83, a fourth upper wiring contact plug 84, and a fourth upper wiring 86 are connected to the third upper wiring 82. The fourth upper wiring contact plug 84 and the fourth upper wiring 86 are configured as one, without a boundary. The seed layer 83 covers the lower and side surfaces of the fourth upper wiring contact plug 84 and the fourth upper wiring 86. The seed layer 83, the fourth upper wiring contact plug 84, and the fourth upper wiring 86 are each included in the same layer as the seed layer 37, the second wiring contact plug 36, and the second upper wiring 38 described above, and contain the same materials.

As illustrated in FIGS. 1, 2, and 3, the height H1 of the upper surface of the pad 14 is lower than the height H2 of the upper surface of the first wiring 50. The height H2 of the upper surface of the first wiring 50 is lower than the height H3 of the upper surface of the third wiring 72. The heights H1, H2, and H3 are defined as distances from the back surface of the semiconductor substrate 2, for example. The film thickness T1 of the second interlayer insulating film 15 on the pad 14, the film thickness T2 of the second interlayer insulating film 15 on the first wiring 50, and the film thickness T3 of the second interlayer insulating film 15 on the third wiring 72 are the same.

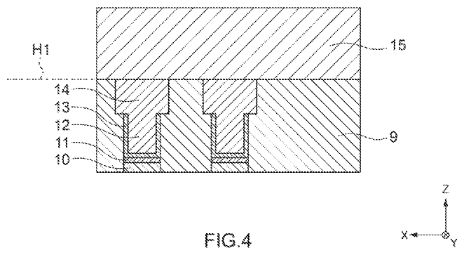

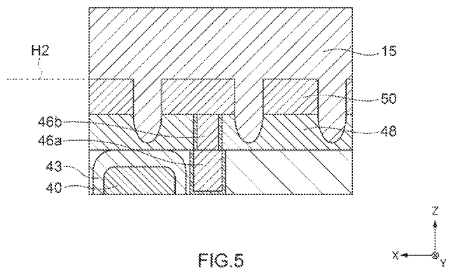

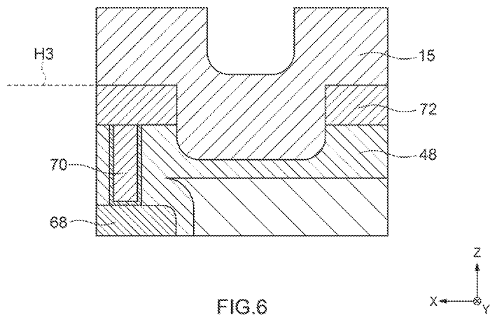

Next, a method of forming the semiconductor device according to the embodiment will be described. The description of the method of forming the semiconductor device according to the embodiment starts from the process by which the first interlayer insulating film 9, the pad 14, the first wiring 50, and the third wiring 72 have been formed. As illustrated in FIGS. 2, 3, and 4, the second interlayer insulating film 15 is formed. The second interlayer insulating film 15 is deposited using chemical vapor deposition (CVD), for example.

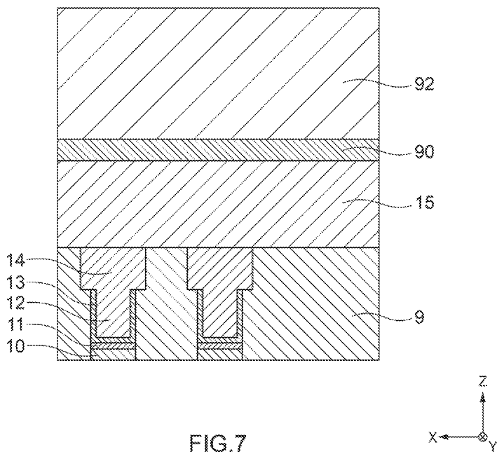

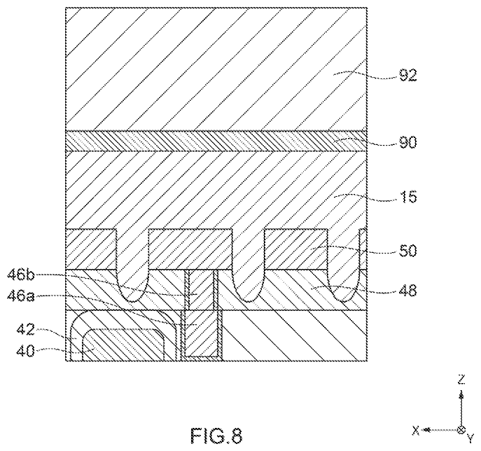

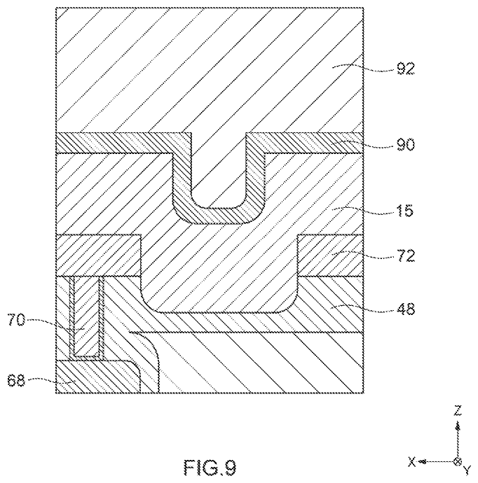

Next, as illustrated in FIGS. 7, 8, and 9, a first sacrificial film 90 and a second sacrificial film 92 are formed on the second interlayer insulating film 15. The first sacrificial film 90 contains silicon nitride, for example, and is deposited by CVD and atomic layer deposition (ALD), for example. The second sacrificial film 92 is an insulating film containing carbon, and is formed by a coating method, for example. The second sacrificial film 92 is formed to have a flat upper surface.

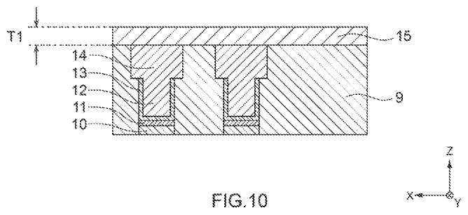

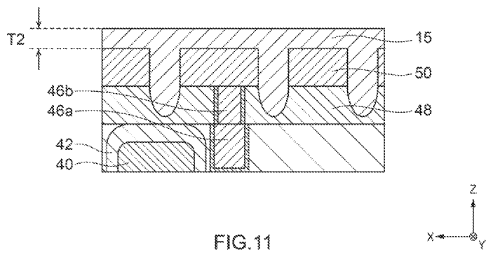

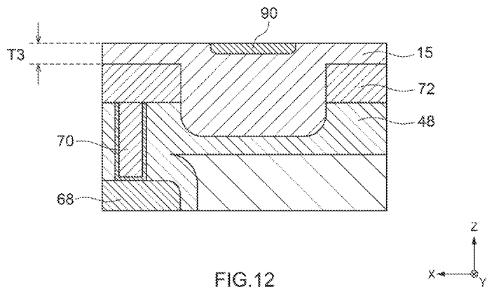

Next, as illustrated in FIGS. 10, 11, and 12, anisotropic dry etching technology is used to etch back the second sacrificial film 92, the first sacrificial film 90, and the second interlayer insulating film 15. The anisotropic dry etching at this stage is performed using conditions whereby the etch rate is the same for the first sacrificial film 90, the second sacrificial film 92, and the second interlayer insulating film 15. The anisotropic dry etching causes the film thickness T1 of the second interlayer insulating film 15 remaining on the pad 14, the film thickness T2 of the second interlayer insulating film 15 remaining on the first wiring 50, and the film thickness T3 of the second interlayer insulating film 15 remaining on the third wiring 72 to be the same thickness.

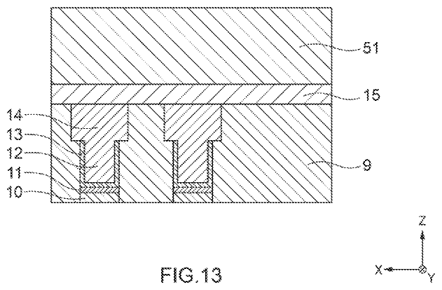

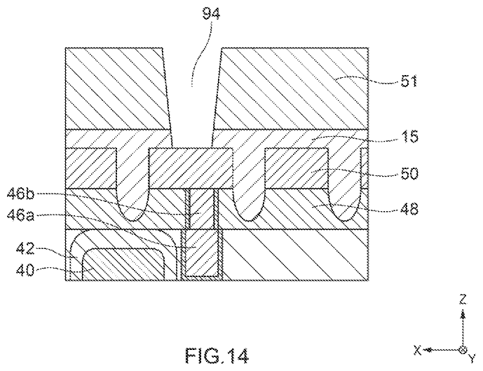

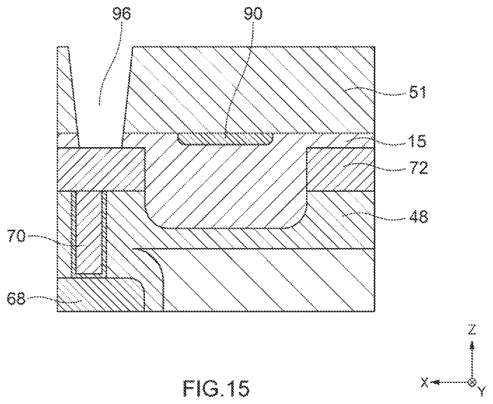

Next, as illustrated in FIGS. 13, 14, and 15, the under-wiring insulating film 51 is deposited on the second interlayer insulating film 15. The under-wiring insulating film 51 is deposited using CVD. Next, a contact hole 94 opening over the first wiring 50 and a contact hole 96 opening over the third wiring 72 are formed. The contact holes 94 and 96 are formed using known lithography technology and anisotropic dry etching technology.

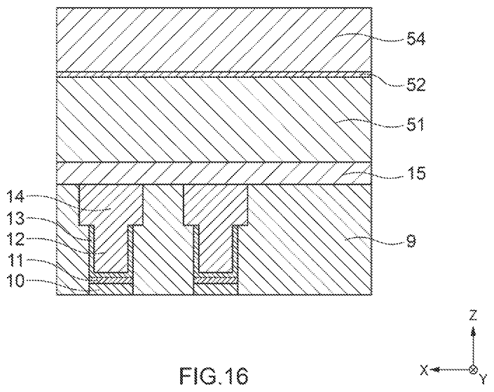

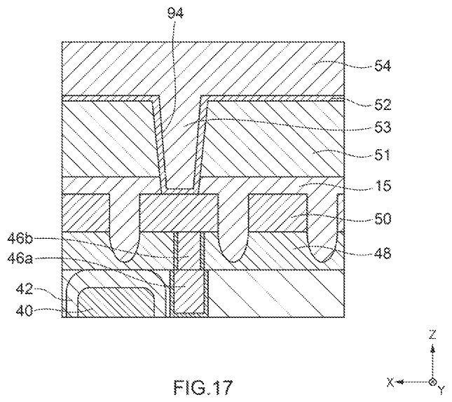

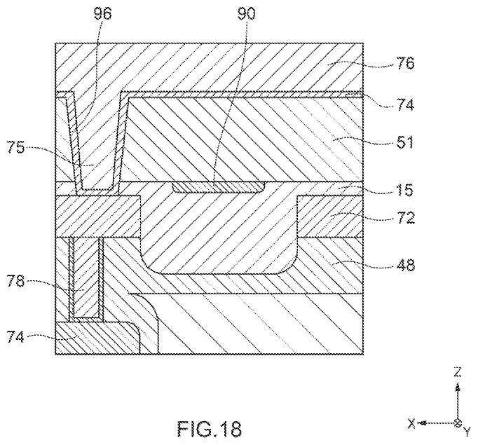

Next, as illustrated in FIGS. 16, 17, and 18, the conducting material to serve as the barrier metal 52 and 74 and the conducting film to serve as the second wiring 54 and fourth wiring 76 are deposited on the under-wiring insulating film 51. The conducting material to serve as the barrier metal 52 and 74 and the conducting film to serve as the second wiring 54 and fourth wiring 76 are deposited by CVD, for example. The barrier metal 52 and 74 are included in the same layer. The second wiring 54 and fourth wiring 76 are included in the same layer.

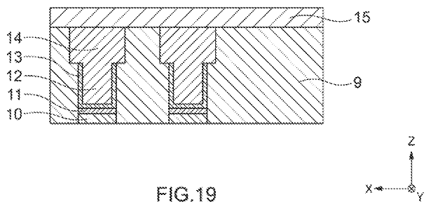

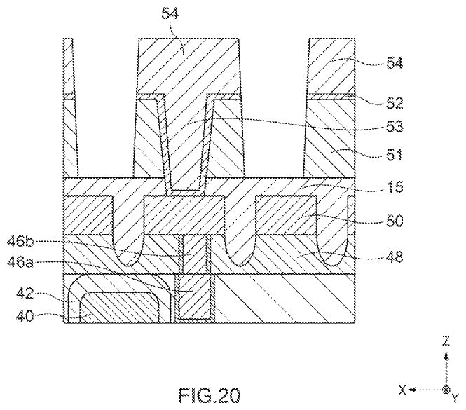

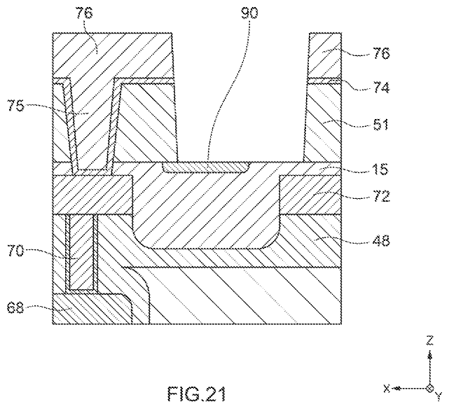

Next, as illustrated in FIGS. 19, 20, and 21, the conducting material to serve as the barrier metal 52 and 74 and the conducting film to serve as the second wiring 54 and fourth wiring 76 are patterned, thereby forming the second wiring contact plug 53, the second wiring 54, the fourth wiring contact plug 75, and the fourth wiring 76. The patterning is performed by known lithography technology and anisotropic dry etching technology. Note that, as illustrated in FIG. 19, in the memory cell region, the conducting material to serve as the barrier metal 52 and the conducting film to serve as the second wiring 54 are removed.

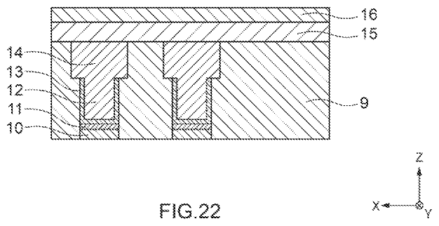

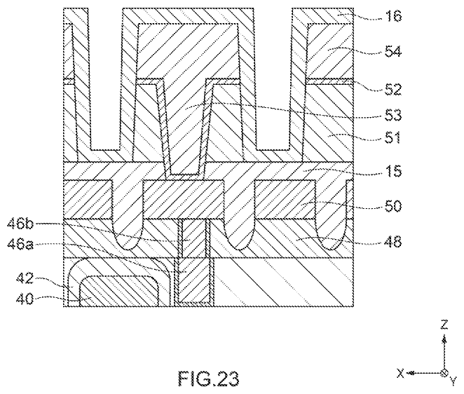

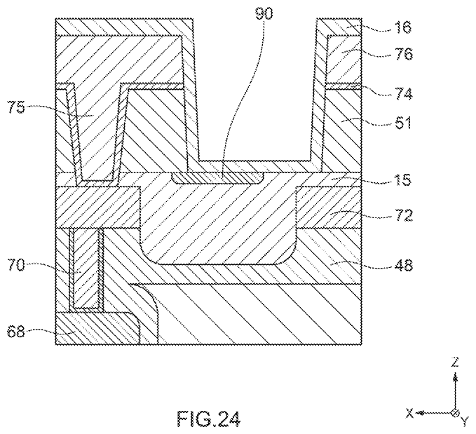

Next, as illustrated in FIGS. 22, 23, and 24, the third interlayer insulating film 16 is deposited to cover the top of the second interlayer insulating film 15, the side surfaces of the under-wiring insulating film 51, the side surfaces of the barrier metal 52 and 74, and the upper and side surfaces of the second wiring 54 and fourth wiring 76. The third interlayer insulating film 16 is deposited using ALD, for example.

Next, as illustrated in FIGS. 1, 2, and 3, in the memory cell region, the capacitors 18, the first upper wiring contact plug 30, the first upper wiring 32, the second wiring contact plug 36, the second upper wiring 38, and the like are formed on the third interlayer insulating film 16. In the sense amplifier or sub-word driver region, the first upper wiring contact plug 60, the first upper wiring 62, the second upper wiring contact plug 64, the second upper wiring 66, and the like are formed. In the peripheral circuit region, the third upper wiring contact plug 80, the third upper wiring 82, the fourth upper wiring contact plug 84, the fourth upper wiring 86, and the like are formed. According to the above processes, the semiconductor device according to the embodiment is formed.

As described above using FIGS. 10, 11, and 12, in the embodiment, anisotropic dry etching technology is used to etch back the second sacrificial film 92, the first sacrificial film 90, and the second interlayer insulating film 15. With this arrangement, the film thicknesses T1, T2, and T3 of the second interlayer insulating film 15 on the pad 14, the first wiring 50, and the third wiring 72 are the same while satisfying the condition that “height of upper surface of pad 14<height of upper surface of first wiring 50<height of upper surface of third wiring 72”. Accordingly, the second interlayer insulating film 15 on the first wiring 50 and on the third wiring 72 does not thin out, nor are the upper surfaces of the first wiring 50 and the third wiring 72 exposed. Consequently, damage imparted to the first wiring 50 or the third wiring 72 by anisotropic dry etching can be suppressed. Therefore, the refresh characteristics and row hammer characteristics of the semiconductor device according to the embodiment can be improved.

As above, DRAM is described as an example of the semiconductor device according to the embodiment, but the above description is merely one example and not intended to be limited to DRAM. Memory devices other than DRAM, such as static random-access memory (EPROM), (SRAM), flash memory, erasable programmable read-only memory (magnetoresistive random-access memory (MRAM), and phase-change memory, for example, can also be applied as the semiconductor device. Furthermore, devices other than memory, including logic ICs such as a microprocessor and an application-specific integrated circuit (ASIC), for example, are also applicable as the semiconductor device according to the embodiment.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a semiconductor substrate having a first region, a second region and a third region;
a first wiring above the first region of the semiconductor substrate;
a second wiring above the second region of the semiconductor substrate;
a third wiring above the third region of the semiconductor substrate; and
a first insulating film on each of the first, second and third wirings;
wherein a height of an upper surface of the first wiring is lower than a height of an upper surface of the second wiring;
wherein the height of the upper surface of the second wiring is lower than a height of an upper surface of the third wiring; and
wherein each of portions of the first insulating film disposed above the first, second and third wirings has an equal film thickness.

2. The apparatus of claim 1, further comprising a second insulating film on the first insulating film.

3. The apparatus of claim 1, wherein the second wiring and the third wiring are included in a same layer.

4. The apparatus of claim 1, wherein the first wiring is included in different layers from the second and third wirings.

5. The apparatus of claim 1, wherein the first wiring comprises tungsten.

6. The apparatus of claim 1, wherein the second and third wirings comprise tungsten.

7. The apparatus of claim 1, wherein the first insulating film comprises silicon dioxide.

8. The apparatus of claim 2, wherein the second insulating film comprises silicon nitride.

9. The apparatus of claim 1, wherein the first wiring is a part of a memory cell array structure, the second wiring is a part of either one of a sense amplifier or a sub-word driver coupled to the memory cell array structure, and the third wiring is a part of a peripheral circuit structure.

10. An apparatus comprising:
a semiconductor substrate having a first region and a second region;
a first wiring above the first region of the semiconductor substrate;
a second wiring above the second region of the semiconductor substrate;
a first insulating film on each of the first, second and third wirings;
wherein a height of an upper surface of the first wiring is lower than a height of an upper surface of the second wiring; and
wherein the first insulating film disposed above each of the first and second wirings has a same film thickness.

11. The apparatus of claim 10, further comprising a second insulating film on the first insulating film.

12. The apparatus of claim 10, wherein the first wiring is included in a different layer from the second wiring.

13. The apparatus of claim 10, wherein the first wiring comprises tungsten.

14. The apparatus of claim 10, wherein the second wiring comprises tungsten.

15. The apparatus of claim 10, wherein the first insulating film comprises silicon dioxide.

16. The apparatus of claim 11, wherein the second insulating film comprises silicon nitride.

17. A method comprising:
forming a first wiring in a first region of a semiconductor substrate;
forming a second wiring having an upper surface higher than that of the first wiring in a second region different from the first region of the semiconductor substrate;
forming a third wiring having an upper surface higher than that of the second wiring in a third region different from the first and second regions of the semiconductor substrate;
forming at least a first insulating film so as to cover the first, second and third wirings;
etching back at least the first insulating film using anisotropic dry etching to leave the first insulating film having a predetermined film thickness.

18. The method of claim 17, further comprising forming a second insulating film different from the first insulating film on the remaining first insulating film after etching back.

19. The method of claim 17, wherein the first insulating film comprises silicon dioxide.

20. The method of claim 17, wherein the first region is included in a memory cell region, the second region is included in a sense amplifier region or a sub-word driver region, and the third region is included in a peripheral circuit region.
